(19) United States
(12) Patent Application Publication
(10) Pub. No.: US 2026/0259270 A1
(43) Pub. Date: Sep. 3, 2026

(54) Methods of Operating Electrochemical Storage Devices Based on Anomaly Clustering, and Software and Systems Including Same

(71) Applicant: SES Holdings Pte. Ltd., Singapore (SG)

(72) Inventor: Weijie Mai, Medford, MA (US)

(21) Appl. No.: 18/846,731

(22) PCT Filed: Mar. 21, 2023
(86) PCT No.: PCT/IB2023/052766

§ 371 Date: Sep. 13, 2024

Related U.S. Application Data
(60) Provisional application No. 63/328,827, filed on Apr. 8, 2022.

(51) Int. Cl. G01R 31/367; G01R 31/36; G01R 31/382; G01R 31/392; H01M 10/44; H01M 10/48

(52) U.S. Cl. CPC G01R 31/367; G01R 31/3646; G01R 31/382; G01R 31/392; H01M 10/441; H01M 10/482

(57) ABSTRACT

Methods of operating electrochemical storage devices, such as secondary batteries, battery modules, and battery cells, using machine-learning models for detecting operating conditions that indicate that one or more electrochemical storages device is/are experiencing an anomaly that may affect its operation. In some embodiments such a method may include deploying an anomaly handler that implements a trained clustering model to identify anomalous operating data and using output of the clustering model to take an operation-control action to control an operation of one or more electrochemical storage devices and/or provide an indication that attention may be needed. In some embodiments a trained detector model is deployed to filter out “normal” operating data so that the trained clustering model handles only “anomalous” operating data, which can drive improvements to the anomaly handler. Methods of training machine-learning models and apparatuses and systems implementing anomaly handlers are also disclosed.

### RELATED APPLICATION DATA

This application claims the benefit of priority of U.S. Provisional Patent Application Ser. No. 63/328,827, filed Apr. 8, 2022, and titled “ANOMALY DETECTION AND/OR ANOMALY CLUSTERING FOR ELECTROCHEMICAL CELLS AND BATTERIES”, which is incorporated herein by reference in its entirety.

### FIELD OF THE INVENTION

The present disclosure generally relates to the field of electrochemical batteries. In particular, the present disclosure is directed to methods of operating electrochemical storage devices based on anomaly clustering, and software and systems including same.

### BACKGROUND

Anomalous behaviors of electrochemical cells, such as cells of lithium-metal secondary batteries, can be caused by any one or more of multiple mechanisms, such as short-circuiting, mechanical damage, and manufacturing defects, among others. It is difficult to develop separate physics-based models to handle each mechanism separately. Consequently, it is difficult to make management systems, such as battery management systems and cell-testing management systems, that adequately manage the operation of cells that may be experiencing an anomaly and/or may appear to be experiencing an anomaly but actually are not. In addition to the challenges in designing physics-based models to handle such mechanisms separately, the challenges are magnified across electrochemical cells of differing chemistries, differing storage capacities, differing output currents and/or output voltages, and differing charging systems, among other things. Consequently, resources needed for designing management systems across multiple families of electrochemical cells and secondary batteries can be significant.

### SUMMARY

In one implementation, the present disclosure is directed to a machine-implemented method of automatedly managing operation of an electrochemical storage device. The machine-implemented method includes receiving a real-time time series based on data from one or more sensors that monitor one or more operating conditions of the electrochemical storage device; clustering the real-time time series into an anomaly group that denotes that an anomaly in the electrochemical storage device has occurred, wherein parameters for the anomaly group have been determined using a machine-learning model trained on a plurality of training time-series data sets; and when the anomaly is determined to have occurred via the processing, taking a predetermined operation-control action based on the anomaly group.

In yet another implementation, the present disclosure is directed to a battery management system that performs a method that includes the above method.

In still another implementation, the present disclosure is directed to a battery testing system that performs a method that includes the method at the beginning of this Summary section.

In another implementation, the present disclosure is directed to a machine-readable medium containing machine-executable instructions for performing a that includes the method at the beginning of this Summary section.

In another implementation, the present disclosure is directed to a method of creating an anomaly handler for a management system for managing operation of an electrochemical storage device. The method includes receiving an input plurality of time-series data sets containing operating data acquired from multiple training storage devices that each share a fundamental design with the electrochemical storage device to be operated by the management system; training a clustering model to create a trained clustering model, wherein the training includes using ones of the input plurality of time-series data sets so as to create a trained clustering model configured to cluster, when the anomaly handler is deployed in the management system, real-time time-series operating data as indicating presence of an anomaly in the electrochemical storage device; and deploying the trained clustering model in the anomaly handler.

In another implementation, the present disclosure is directed to a method of making a management system for operating an electrochemical storage device. The method includes performing the above method of creating an anomaly handler to create the anomaly handler; and deploying the anomaly handler in the management system

### BRIEF DESCRIPTION OF THE DRAWINGS

For the purpose of illustration, the accompanying drawings show aspects of one or more embodiments of the invention(s). However, it should be understood that the invention(s) of this disclosure is/are not limited to the precise arrangements and instrumentalities shown in the drawings, wherein:

FIG. 1 is a high-level block diagram illustrating an example management system made in accordance with the present disclosure for managing operation of one or more electrochemical storage devices;

FIG. 2 is a flowchart depicting an example method of the present disclosure for automatedly managing operations of an electrochemical storage device, such as an electrochemical storage device shown in FIG. 1;

FIG. 3 is a flowchart depicting an example method of the present disclosure for creating an anomaly handler for a management system for managing operation of an electrochemical storage device, such as the management system shown in FIG. 1;

FIG. 4 is a diagram illustrating operation of an example autoencoder that can be used in a detector model of the present disclosure, such as the trained detector model of FIG. 1, to determine reconstruction errors that characterize time series input into the autoencoder;

FIG. 5 is a diagram illustrating data used to train the autoencoder of FIG. 4, the resulting detector model, and example reconstruction errors that the autoencoder has assigned to data input into the autoencoder; and

FIG. 6 is diagram illustrating an example anomaly handler made in accordance with the present disclosure and using the same data and reconstruction visualizations used in FIGS. 4 and 5.

### DETAILED DESCRIPTION

### GENERAL DESCRIPTION

In some aspects, the present disclosure is directed to management systems for managing the operation of one or more electrochemical storage devices, such as one or more cells that make up or are part of a secondary battery, a secondary battery itself, or a module of a secondary battery, or one or more cells, secondary batteries, or modules, being tested in a storage-device testing system, among others. In some embodiments, a management system of the present disclosure includes an anomaly handler that has been trained using a plurality of time-series training data sets that allows the anomaly handler to analyze real-time time-series operating data, detect an anomaly therein, and cluster the anomaly into an appropriate cluster (group). Embodiments of a management system of the present disclosure can be configured to use the presence of the anomaly and the type of the anomaly to automatically take an operation-control action, such as removing an affected electrochemical storage device from service, changing a charging protocol for the affected electrochemical storage device, triggering an indicator lamp relating to the anomaly, or causing a display device to display the type of the anomaly, among many others, and any practicable combination thereof. Examples of anomaly types include, but are not limited to, over-voltage, overcharge, and short circuiting, among others. As will become apparent from reading this entire disclosure, benefits of a management system of the present disclosure can include detecting and/or identifying anomalies in electrochemical storage devices before failure without knowing the mechanisms and/or root causes of anomalies and automatically taking one or more appropriate actions based on detecting/identifying the anomalies.

In some aspects, the present disclosure is directed to methods, and/or corresponding software, for managing the operation of electrochemical storage devices, such as any of the electrochemical storage devices noted above, among others. In some embodiments, methods for managing the operation of electrochemical storage devices in accordance with the present disclosure may include receiving real-time time-series data regarding the operation of each electrochemical storage device, automatically determining whether or not an anomaly is present based on the real-time time-series data, automatically clustering/grouping the anomaly detected, and taking an operation-control action based on the type of the anomaly detected. Non-limiting examples of operation-control actions are listed above. In some embodiments, the abilities to determine whether an anomaly is present and to cluster/group the anomaly are based on an anomaly handler that has been trained using a plurality of time-series training data sets that allows the anomaly handler to analyze real-time time-series operating data, detect an anomaly therein, and cluster/group the anomaly.

In some aspects, the present disclosure is directed to methods, and/or corresponding software, for creating an anomaly handler, for example, an anomaly handler that can be used in any of the foregoing methods and systems for operating electrochemical storage devices. In some embodiments, a method of creating an anomaly handler may include training a clustering model using a plurality of training data sets each containing operating data collected from a plurality of electrochemical storage devices that are each designed to be the same as or similar to (e.g., may have differing numbers of like cells) the electrochemical storage device(s) with which the anomaly handler created will be used. In some embodiments, the clustering model is trained using only time-series data that represents an occurrence of an anomaly. The anomaly handler may be based on any one or more suitable machine-learning algorithms.

In some embodiments, the anomaly handler includes a trained detection algorithm (e.g., an autoencoder algorithm) and a trained clustering algorithm, wherein the trained detection algorithm has been trained with a training-data set that includes both time-series data that represents normal operation of the electrochemical storage devices and time-series data that represents anomalous operation of the electrochemical storage devices. In some embodiments, the ratio of normal time-series data to anomalous time-series data in the training-data set for the detector model may be the same as or similar to ratios of such data experienced during testing of actual electrochemical storage devices during the process of commercializing a particular electrochemical storage device design or design family. For example, the ratio of normal time-series data to anomalous time-series data in the training-data set may be equal to or greater than 95:1, such as 95:1, 97:1, 99:1, 99.5:1, or 99.9:1 or greater, among others.

In some embodiments, the anomaly handler may additionally include a filter that, during deployment of the anomaly handler in a management system, operates on output of the detector model and sends only real-time time-series data to the clustering model that represents occurrence of an anomaly. In embodiments that include both a trained detector model, a trained clustering model, and a filter, the detector model simply finds any anomaly without knowledge of the severity of the anomaly or even the type of anomaly, and the clustering model clusters anomalies into differing anomaly groups, which in some embodiments may include groups indicating differing severities. Implementing the detector model and filter reduces processing time and resources for executing the trained clustering model and increases the performance of the anomaly handler overall. For example, if real-time time-series data were input directly into a trained clustering model, it would mean that, during model training, both normal and anomalous training data would be used. Otherwise, there would not be a cluster/group corresponding to normal time-series data. Other drawbacks of imputing all real-time time-series data directly into a trained clustering model include time-consuming training of the clustering model and creating a highly unbalanced dataset. For example, if 99.9% of the time series in a dataset belong to one cluster/group (here, the normal time series) and a naïve model is trained to predict that all of the time-series are normal, then the model accuracy will be 99.9%, but it will be useless for clustering anomalies.

In other instantiations, alternative machine-learning models can be used in the anomaly handler, such as any suitable unsupervised model that can be implemented using machine-learning methods. Examples of unsupervised machine-learning methods/constructs include, but are not limited to, one or more dimension convolutional neural network (e.g., a 1D or a 3-D CNN) autoencoders, long short-term memory (LSTM) autoencoders, random forest handlers, and support vector machines, among others. Generally, and as those skilled in the art will appreciate, most unsupervised machine learning methods can be adjusted within the ordinary skills in the art to perform anomaly detection and/or clustering for use in operation-control methods and systems of this disclosure.

The foregoing and other aspects are discussed and exemplified below in detail.

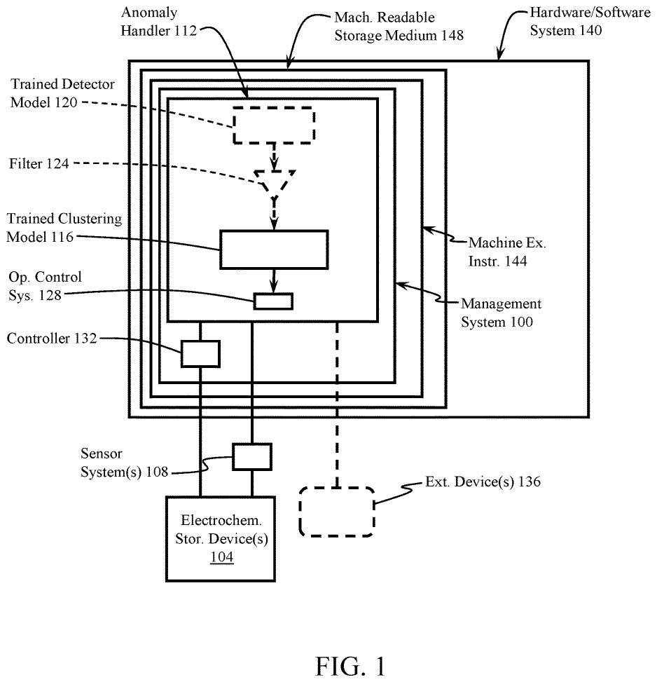

Referring now to the drawings, FIG. 1 illustrates an example management system 100 having aspects and features in accordance with the present disclosure. As alluded to above, the management system 100 may be adapted for use in any of a variety of deployments, such as in a battery management system (BMS) that manages one or more electrochemical storage devices (singly and collectively represented at 104) during the use of such electrochemical storage device(s) or in a testing controller that controls testing of one or more electrochemical storage device, among other deployments. As will become apparent from reading this entire disclosure, the management system 100 uses time-series data regarding the operation of the electrochemical storage device(s) 104 to train one or more machine-learning models. The type of data in the time series can vary with the design of the management system 100 and corresponding machine-learning model(s). For example, the time-series data may include, but not be limited to, measured data, such as voltages, currents, temperatures, and/or pressures, in any practicable combination, or calculated data, such as states-of-charge (SOCs), determined using measured data, and any practicable combination of measured and calculated data. Measured data may be acquired via one or more sensor systems (singly and collectively represented at 108 that comprises one or more appropriate sensors (e.g., voltage, current, temperature, pressure, etc.) (not shown) and any needed hardware (e.g., analog-to-digital converter(s), signal-conditioning circuitry, etc.) (not shown). The sensor system(s) 108 may be a central sensor system or plurality of distributed sensor systems (e.g., one per each of multiple electrochemical storage devices), or a hybrid of a central sensor system and plurality of distributed sensor systems. The particular type(s) of sensor system(s) 108 used is/are beyond the scope of this disclosure, and those of ordinary skill in the art will readily understand how to provide such sensor system(s) 108.

In this example, the management system 100 includes an anomaly handler 112 that is designed and configured to, after training and deployment, cluster or group (hereinafter “cluster/group”) each input real-time time series concerning the operation of the electrochemical device(s) into an appropriate cluster/group and then to take an operation-control action based on the determined cluster/group. Examples of clusters/groups and examples of corresponding operation-control actions are each listed above.

The example anomaly handler 112 includes a trained clustering model 116 that operates on input real-time time-series data regarding the operation of the electrochemical storage device(s) 104 to cluster/group the time-series into individual clusters/groups. As discussed above, the trained clustering model 116 can be any suitable machine-learning algorithm that is able to perform the clustering/grouping. As discussed elsewhere herein, the trained clustering model 116 is trained using any suitable training data relevant to the design deployment of the management system 100. In some embodiments, an output of the trained clustering model 116 in response to a given input real-time time series may be a group identifier that identifies a group to which the trained cluster model has determined that the input real-time time series belongs. In some embodiments, differing groups may correspond to differing types of anomalies or to differing levels of severity of the anomalies, or a combination of both differing types of anomalies and differing levels of severity of the anomalies.

The anomaly handler 112 may optionally, and in some cases preferably for reasons discussed below in the next section, include a trained detector model 120 that generates a data characterization for each real-time time series input into the anomaly handler 112. As discussed in more detail below, the trained detector model 120 can be used to simplify the anomaly handler 112, decrease the amount of processing time and processing resources needed, and increase the accuracy and precision of the anomaly handler. As described below in detail, in some embodiments, the trained detector model 120 comprises a trained autoencoder that has been trained to determine, for each input real-time time series, a reconstruction error as the data characterization. An example of training a detector model to arrive at the trained detector model 120 is provided below in the next section for an autoencoder.

In conjunction with the trained detector model, the anomaly handler 112 may also optionally include a filter 124 that passes any time series having a data characterization that meets the filter criterion(ia). As an example, in the context of using reconstruction errors as the data characterizations and wherein the reconstruction errors increase with severity of the anomalies, the filter 124 may utilize a threshold that filters out all real-time time series where the corresponding reconstruction error is below the threshold and passes all real-time time series to the trained clustering model 116 where the corresponding reconstruction error is at or about the threshold. In this manner, only anomalous real-time time series are passed to the trained clustering model 116, thereby achieving the benefits mentioned above and described in more detail below.

The management system 100 includes an operation-control system 128 that takes a predetermined operation-control action based on a corresponding group identifier that the trained clustering model 116 has generated. Examples of operation-control actions are listed above. When the trained clustering model 116 is configured to recognize multiple differing groups, the operation-control system 128 may include multiple predetermined operation-control actions. Depending on the groups, the multiple operation-control actions may map one-to-one with the multiple groups or two or more groups may map to a single operation-control action. As an example of the latter, two groups may represent anomalies so severe that the relevant electrochemical storage device must be shut down, so in response to the operation-control system 128 receiving an group indicator for either of these two groups, it will perform an action to shut down the operation of the electrochemical storage device, for example, by issuing a shut-down command to a controller 132 or other part of the management system 100. In some embodiments, an operation-control action may involve causing one or more external devices (singly and collectively represented at 136) to display one or more indications regarding the detection of an anomaly. Each external device 136 may be any device external to the management system 100, such as, but not limited to, a lamp indicator located at any practicable location, such as on a housing of a battery or battery module or on a console located remotely from the battery or battery module, a graphical display, such as a computer display screen, a display screen of an electric or electric-hybrid vehicle, a display screen of a battery system (e.g., a grid-power storage system), or a display screen of a mobile device (e.g., smartphone), an auditory device, or a haptic device, among others. Fundamentally, there is no limitation on the type of external device 136 that the operation-control system 128 can control. In some embodiments, the operation-control system 128 may issue one or more control commands that cause the external device 136 to display the indication(s) in any suitable manner. Example indications include, but are not limited to, illuminating a warning lamp, sounding an alarm, displaying a warning message, and displaying instructions, among others, and any practicable combination thereof.

As those skilled in the art will readily appreciate, the management system 100 can be implemented in any suitable software/hardware system 140, including, but by no means limited to, a system-on-chip software/hardware system, a centralized computing software/hardware system, a distributed computing software/hardware system, an on-cloud software/hardware system, and an edge-type software/hardware system, and any practicable combination thereof. Any or all of the models described and listed herein, or apparent from reading this entire disclosure, and any algorithms and/or any machine-executable instructions 144 needed for performing any function disclosed or suggested in this disclosure or apparent from reading this entire disclosure may be stored in any suitable machine-readable hardware storage medium 148, which includes any one or more hardware storage memories of any one or more of suitable types, including, but not limited to, long-term machine memory (flash memory, solid-state memory, ROM, optical memory, magnetic memory, etc.), short-term machine memory (e.g., RAM, cache, etc.). Fundamentally, there are no limitations on the type(s) of hardware storage memory(ies) that can be used. It is particularly noted that the term “hardware” in “machine-readable hardware storage medium” indicates the exclusion of any sort of transient medium, such as signals on a carrier wave and sequenced pulses that carry digital information. All of the foregoing and other suitable software/hardware systems 140 are ubiquitous and commonplace, and therefore need not be described in any more detail for those skilled in the art to make and use all features and aspects of this disclosure to their fullest scope without undue experimentation.

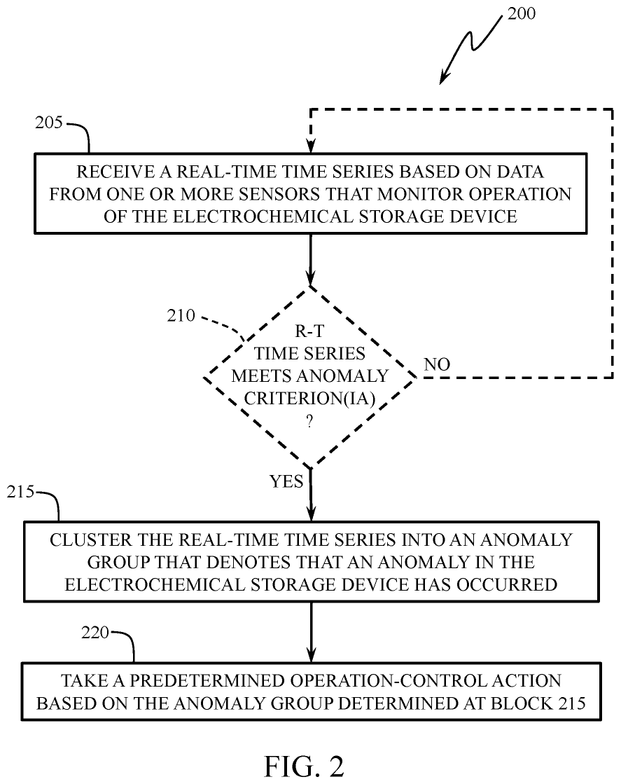

FIG. 2 illustrates an example method 200 of automatedly managing operations of an electrochemical storage device, such as any of the electrochemical storage devices mentioned above. As those skilled in the art will readily appreciate, the method 200 is a machine-implemented method, which may be implemented in machine executable instructions deployed in any of a variety of hardware/software systems, such as the hardware/software systems mentioned above in the context of the hardware/software system 140 of FIG. 1.

Referring to FIG. 2, the method 200 includes, at block 205, receiving real-time time series based on data from one or more sensors that monitor one or more operating conditions of the electrochemical storage device. As discussed above, the real-time time series contains operating data that may be sensor data (e.g., digitized and/or conditioned signals output from the sensor(s)) and/or calculated data (e.g., SOC data) based on sensor data.

At optional block 210, the method 200 may include determining whether or not the real-time time series meets at least one anomaly-indicating criterion. Relative to the anomaly handler 112 of FIG. 1, block 210 may involve using the trained detector model 120. As discussed above, the determination at block 210 may include determining a data characterization for the real-time time series, such as a reconstruction error, and determining whether or not the data characterization meets that anomaly-indicating criterion(ia). In an example, and as discussed above, if a reconstruction error is used, the reconstruction error can be determined using a trained autoencoder. Those skilled in the art will readily appreciate that any of a number of alternative machine-learning models can be used at optional block 210.

If the real-time time series meets the anomaly criterion(ia), then the method 200 may include proceeding with clustering at block 215. Relative to the anomaly handler 112 of FIG. 1, optional block 210 may involve the filter 124. For example, and in the context of using a reconstruction error, block 210 may include comparing the reconstruction error (data characterization) determined for the real-time time series to a threshold value and then only passing the real-time time series on to block 215 when the reconstruction error meets or exceeds the threshold value. Those skilled in the art will readily appreciate that this is but one example of how block 210 can be implemented.

At block 215, the method 200 includes clustering the real-time time series into an anomaly group that denotes that an anomaly in the electrochemical storage device has occurred, wherein parameters for the anomaly group have been determined using a machine-learning model trained on a plurality of training time-series data sets. Relative to the anomaly handler 112 of FIG. 1, block 215 may involve the trained clustering model 116. As discussed above, the trained machine-learning model may be any suitable machine-learning model, such as a clustering model. When block 210 is present in the method 200, the training time-series data sets may only include anomalous time-series data, i.e., time series containing operating data from electrochemical devices that experienced an anomaly of the type targeted by the method 200. Benefits of having the machine-learning model trained only on anomalous data are discussed above. Also when block 210 is present in the method 200, the clustering performed at block 215 is performed only when the real-time time series indicates that an anomaly has occurred in the electrochemical storage device. Again, the benefits of operating only on real-time time series indicating an anomaly are discussed above. If the real-time time series does not meet the anomaly criterion(ia) at block 210, then the method 200 may loop back to receiving another real-time time series at block 205 and cycling back through the method.

At block 220, the method 200 includes taking a predetermined operation-control action based on the anomaly group to which the clustering of block 215 assigned the real-time time series. Relative to the anomaly handler 112 of FIG. 1, block 220 may involve the operation control system 128. As discussed above, the predetermined operation-control action may be any type of operation-control action applicable to the assigned anomaly group. Although not shown, following the taking of the predetermined operation-control action at block 220, the method 200 may loop back to block 205 or take another action, for example, if the predetermined operation-control action taken is to shut down the electrochemical device, among other things.

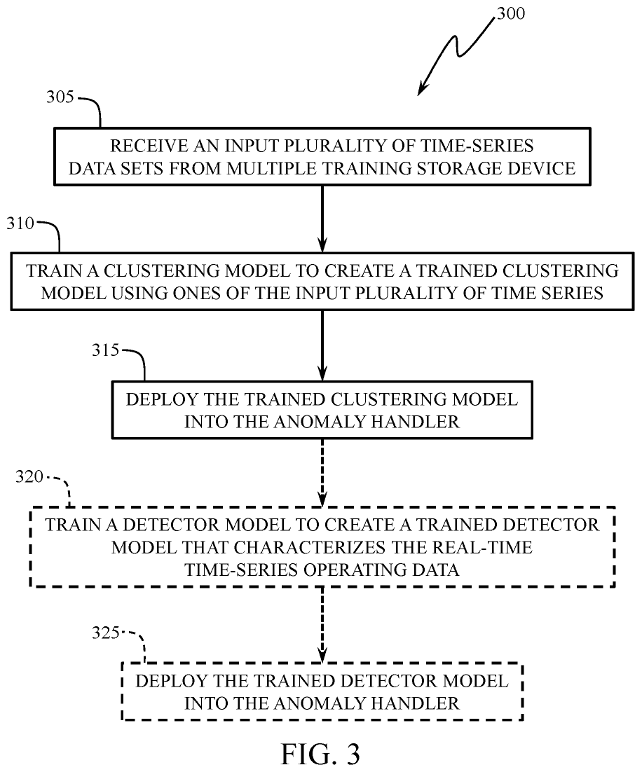

FIG. 3 illustrates another example method 300 of the present disclosure. In this example, the method is a method of creating an anomaly handler for a management system for managing operation of an electrochemical storage device, such as the anomaly handler 112 of the management system 100 of FIG. 1. Referring to FIG. 3, the method 300 includes, block 305, receiving an input plurality of time-series data sets containing operating data acquired from multiple training storage devices that each share a fundamental design with the electrochemical storage device to be operated by the management system. Each training storage device may be in the same family as the electrochemical storage device with which the anomaly handler is deployed. For example, being in the same family may mean, among other things, that each storage device in the family uses identical electrochemical cells and/or battery modules, perhaps in differing numbers, and the electrochemical cells and/or battery modules are electrically connected with one another in the same manner from storage device to storage device. For example, in a given family, all of the electrochemical cells and/or battery modules may be all connected together in electrical series within a given family, or may be all connected together in electrical parallel, or may be all connected together with a set arrangement of series and parallel connection, such as every four electrochemical cells connected together in electrical series, with all of the groups of four electrochemical cells connected together in electrical parallel. Many other variants are possible.

At block 310, the method 300 includes training a clustering model to create a trained clustering model, such as the trained clustering model 116 of FIG. 1. The training of the clustering model includes using ones of the input plurality of time-series data sets received at block 305 so as to create a trained clustering model configured to cluster, when the anomaly handler is deployed in the management system, real-time time-series operating data as indicating presence of an anomaly in the electrochemical storage device. In some embodiments, the input plurality of time-series data sets consists only of anomalous data sets, i.e., time series containing operating data from electrochemical devices that experienced an anomaly of the type targeted by the desired anomaly handler made using the method 300. Advantages of this are discussed above. At block 315, the method 300 includes deploying the trained clustering model into the anomaly handler.

The method 300 may optionally include, at block 320, training a detector model to create a trained detector model that, when the anomaly handler is deployed in the management system, generates a data characterization of the real-time time-series operating data. In the context of FIG. 1, block 320 may involve training of the detector model that becomes the trained detector model 120. At related optional block 325, the method 300 includes deploying the trained detector model into the anomaly handler.

The foregoing are but two examples of a variety of methods that can be devised and implemented using the fundamental features and aspects disclosed herein. Those skilled in the art will readily be able to devise and implement such variety of methods using only ordinary skill in the art and without undue experimentation using the present disclosure as a guide.

### EXAMPLE PROCESS OF CREATING AN ANOMALY HANDLER

In some embodiments, an unsupervised machine-learning model, or “detector model”, is trained for anomaly detection by learning from a large amount of cycling data for the electrochemical-storage-device design under consideration. Unsupervised learning means that during training the detector model does not know which data are normal and which data are not normal. After training with data, the detector model learns the behavior of normal modules fairly accurately, as they occur relatively very often. In contrast, anomalous behaviors are relatively very rare, and, thus, the detector model cannot learn their behavior as accurately. This difference is then used to detect anomalies. Compared with physics-based models, machine-learning models of the present disclosure are defined simply based on the distribution of data and thus can cover most, if not all, types of anomalies.

After the detector model has detected anomalies, the detected anomalies can be used to train another unsupervised model, i.e., a “clustering model”, that automatically separates the anomalies into multiple clusters, or “groups”. By analyzing these groups, the clustering model can learn the type of anomaly that has been detected, such as over-voltage, overcharge, impending short circuiting, etc.

Following is a discussion of an example process of creating an anomaly handler for use with a group of battery modules (electrochemical storage devices) having the same fundamental design but wherein each battery module does not necessarily have the same number of cells as the other battery modules in the group. It is noted that while this example is directed to battery modules, those skilled in the art will readily understand modifications to the process needed to use the process with individual cells, batteries, and other electrochemical storage devices after reading this entire disclosure.

Data Preprocessing. Because the number of voltage measurements is proportional to the number of cells within a battery or module, the number of voltage measurements within a set of time-series data can differ among multiple batteries/modules. This makes modeling difficult, as a detector model will typically require a fixed number of inputs. In some embodiments of the present disclosure, summary statistics are generated using raw operating data (e.g., voltage measurements) to standardize the size of the input time series. This ensures that the size of each input data set is the same regardless of the number of cells in any particular battery/module, while maintaining as much raw information as possible.

As an example, if a battery/module, has 10 cells connected in series, and the time window used is 20, then the input to the model will be a 10×20 matrix (here, 10 voltages at each timestamp and a total of 20 timestamps). This fixed input size can be used if the battery/module design has a fixed number of cells. However, as the number of cells could vary in a particular design family, other batteries/modules in the family could have, for example, 6 cells connected in series or 12 cells connected in series. Correspondingly, the inputs to the model would be 6×20 and 12×20 matrices for the 6- and 12-cell variants, respectively. Since machine-learning models typically only accept a fixed input size, using unprocessed input data would require training separate models for each battery/module variant, which is not desirable. Consequently, it is desirable to process the time series to standardize the size of each input data set. One example of such data processing is to extract the statistics of cell voltages and reduce the number of data to a fixed number at each timestamp. This can be represented in this example by a function f that performs the following transformation: f([(N_{C})×(N_{TS}) matrix])=[(N_{IDP})×(N_{TS}) matrix], wherein N_{C} is the number of cells in the battery/module, NTs is the number of time-stamps at which the voltage readings are taken, and N_{IDP} is the fixed number of input data points (voltages) that the corresponding model requires. In this way, no matter how many cells are in a particular battery/module variant, the input size will be the same. In other words and for this example, a model can be trained and applied to a battery/module within a design family no matter how many cells are connected in series. Those skilled in the art will readily appreciate that the above example is merely illustrative and that parameters, such as the type of readings being differing and the number of reading types being greater than one.

Detection Training. In this example, a one-dimensional (1-D) CNN autoencoder is used to reconstruct each time-series data set for a battery module, and a reconstruction error for each time-series data set is then used for anomaly detection. A 1-D CNN is a machine-learning construct that can significantly reduce the size of the detector model by using a convolutional layer. It is also a flexible model and can be retrained using additional time-series data, such as temperature, pressure, etc., to improve the performance of the detector model.

Clustering Training: After training the detector model, the anomalies it has detected can be automatically separated into one or more groups. Based on the features of each anomaly group, a label, such as “over-voltage”, “overcharge”, “short-circuited”, etc., identifying the type of anomaly for each group can be created and provided to a clustering model. Then, following training of the clustering model and deployment of the detection and clustering models, the trained detector model will detect anomalies and the trained clustering model will then cluster the anomalies by type.

Based on these clusterings, corresponding operating-actions can be taken, depending on the severity of each type of anomaly. It is noted that in this example, the combination of the detector model and the clustering model makeup the anomaly handler.

### Aspects of the Example Process of Creating an Anomaly Handler

### 1. Training the Detector Model

As noted above, in this example an autoencoder detector model is deployed to detect anomalies by reconstructing input time-series data, which may include voltages, states of charge (SOCs), temperatures, and/or pressures, among other collected data, which may be sensed or calculated from sensed data. An autoencoder model is typically composed of two parts: an encoder and a decoder. Encoding is an information-compressing process (e.g., 10 inputs compressed to 2 encoded values), and then decoding attempts to reconstruct the input using the encoded information (e.g., output 10 values using the 2 encoded values). During the training process, time-series training data sets will be input into the autoencoder model one-by-one, and the encoder will try to learn the most informative features in the input data, while the decoder will learn to reproduce input as accurately as possible within limits of the autoencoder detector model.

### 2. Define Threshold of Normality

With training, an autoencoder detector model learns how to reconstruct the input. However, due to the information being compressed in the encoder, it is impossible for the decoder to perfectly reconstruct the input. For each time-series training data set, a reconstruction error can be calculated, and the collection of reconstruction errors from the overall training can be analyzed to see how all the reconstruction errors distribute, which distribution will correspond to the distribution of the input. Normal, i.e., non-anomalous, input data will occur very often. Consequently, the autoencoder detector model will learn to reproduce normal input data accurately, leading to low reconstruction error. In contrast, anomalous input data are relatively rare as compared to normal input data. As a result, the autoencoder detector model cannot reproduce them as accurately, leading to higher reconstruction error.

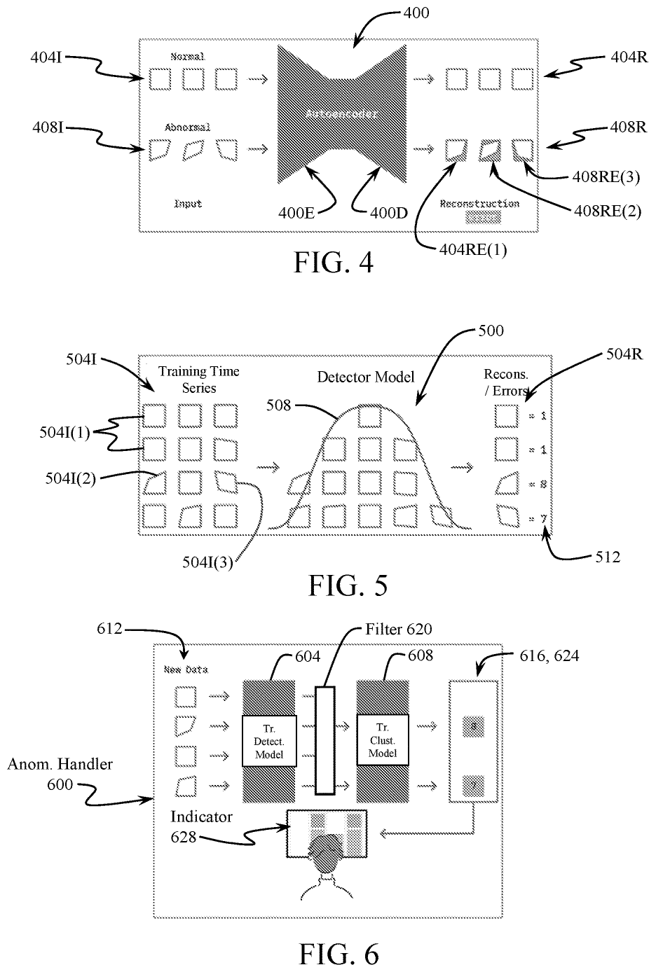

FIG. 4 illustrates the general principles of an autoencoder 400, but using geometric shapes to represent the input data and the reconstructions of the input data so that the reader can readily visualize the principles. Of course, however, in the context of the present disclosure, the illustrated shapes represent operating time-series data from one or more electrochemical devices.

The autoencoder 400 includes an encoder 400E and a decoder 400D, which functions as discussed above, respectively, to compress the input information, here represented by normal input (squares 404I) and anomalous input (quadrilaterals 408I) into encoded values (not shown), and create reconstructions (squares 404R) of the normal input and reconstructions (quadrilaterals 408R) of the anomalous input. In FIG. 4, the reconstruction errors, i.e., the deviations in the reconstructions (squares 404R and quadrilaterals 408R) from normal input, are illustrated by shaded regions 408RE(1) through 408RE(3).

After training, a reconstruction-error threshold can then be defined based on the reconstruction errors of the overall training input data set. For example, if the reconstruction error is less than 2, then the input data may be deemed normal. In contrast, if the reconstruction error is equal to or greater than 2, then the input data may be deemed anomalous and, therefore, indicative of an anomaly being present in the corresponding electrochemical storage device. It is noted that the selection of threshold will affect the recall and precision of the model. A lower threshold usually implies higher recall but lower precision and more “false alarms” will result.

FIG. 5 visually illustrates an example detector model 500 using the same visualization scheme used for the example autoencoder 400 of FIG. 4. FIG. 5 shows the input training data 504I (quadrilaterals of differing shapes) and the corresponding trained detector model 500 and its as-trained statistical distribution 508 of reconstructed input 504R (quadrilateral of differing shapes).

FIG. 5 also shows a subset of resulting reconstruction errors 512 and representational sets of the input training data 504I(1) through 504I(3) corresponding to the respective reconstruction errors.

### 3. Training the Clustering Model

After defining the threshold for the detector model, many time-series in the input training data set will be tagged as anomalous. These anomalous time-series are then used to train a clustering model (e.g., a clustering model) that learns to separate the detected anomalous time series into differing groups corresponding to differing types of anomalies. For example, in FIGS. 4 and 5 squares are considered normal and each quadrilateral that is not square could be labeled as anomalous, depending on how different it is from a perfect square. The trained clustering model will identify the detected anomalies into differing groups, i.e., differing anomaly types. Again, using geometric shapes to assist with visualization and considering a square to be normal, the trained clustering model may be trained to cluster anomalies, i.e., non-squares, such as circles (in the context of the present disclosure, e.g., overcharge), triangles (e.g., over-discharge), trapezoid (e.g., anomalous behavior between current and voltage), etc. Using the trained clustering model, not only can the detector model detect an anomaly, but the overall anomaly handler can also get a sense of what type of anomaly the detector model has detected.

FIG. 6 illustrates an example anomaly handler 600 of the present disclosure using the same data and reconstruction visualizations used in FIGS. 4 and 5 for ease of understanding. Of course, and as mentioned above, the various quadrilateral shapes shown in FIG. 6 represent input time-series data sets in the context of the present disclosure. As seen in FIG. 6, the anomaly handler 600 includes a trained detector model 604 and a trained clustering model 608. As discussed above, the trained detector model 604 receives inputs (here, shapes 612) that are either normal or anomalous and outputs reconstruction errors 616 for these shapes. It is noted that while FIG. 6 implies that the trained detector model 604 is receiving the inputs (shapes 612) in parallel with one another, the trained detector model may indeed, and typically will, receive the inputs in series with one another. The same parallel-versus-series nature may equally apply to other aspects depicted in FIG. 6.

Each reconstruction error 616 is then provided to a filter 620, which in this case and consistent with the example of FIG. 5, passes any real-time time series 624 having a reconstruction error equal to or greater than 2 to the trained clustering model 608, filtering out any normal, and more abundant, real-time time series. The trained clustering model 608 then clusters the filtered real-time time series into a cluster/group and outputs an indicator 628 of the anomaly group for use by an operation-control system (not shown) that the anomaly handler is used with. In the example illustrated in FIG. 6, the two squares in the inputs 612 have a reconstruction error of about 0, so the filter 620 did not pass the corresponding time-series data sets to the clustering model 608. However, the other two inputs 612 (non-square quadrilaterals) have reconstruction errors of 8 and 7, respectively, and so the filter 620 passed the corresponding time-series data sets to the clustering model 608 for clustering.

### 4. Deployment of the Anomaly Handler

With continued reference to FIG. 6, after the detection and clustering models 604 and 608 of the anomaly handler 600 are trained and validated, the anomaly handler can be deployed, for example, in a BMS (e.g., on-board, on an edge-computing device, in the cloud, etc.) to provide real-time safety assurance or in a testing system, among other systems. Once real-time time-series data regarding the operation of one or more electrochemical storage devices is obtained, the real-time time-series data is fed into the trained detector model 604, which outputs a corresponding reconstruction error. This reconstruction error is then compared with the predefined threshold in a filter 620, and the real-time time-series data may be tagged as anomalous if the error is higher than the threshold. Once detected, the time-series data may be fed into the trained clustering model, which will output an anomaly indicator corresponding to the cluster/group to which the trained clustering model assigns the detected anomaly. A BMS or other system can use this anomaly indicator to take corresponding actions. For example, depending on the severity of the anomaly, the anomaly handler may determine an electrochemical storage device to be anomalous and should be replaced, controlled to undergo a healing process, or used in a limited manner until danger is removed, among other operation actions.

Example benefits of disclosed anomaly handlers include but are not limited to:
1. They do not set thresholds for each individual variable (current, voltage, temperature, pressure, etc.), but instead have an overall anomaly score (e.g., reconstruction error) for each electrochemical storage device's behavior based on measurement data.
2. They are not limited to any particular type of anomaly. Each may be designed such that it can detect all anomalies as long as the measurement data is of a suitable character.
3. They do not require understanding of the failure mechanism. They rely purely on the historical operating (e.g., cycling) data to define normal and anomalous operating conditions.
4. They allow real-time anomaly detection and do not require interrupting usage of the electrochemical storage device to obtain additional signals for anomaly detection.

Various modifications and additions can be made without departing from the spirit and scope of this disclosure. Features of each of the various embodiments described above may be combined with features of other described embodiments as appropriate in order to provide a multiplicity of feature combinations in associated new embodiments. Furthermore, while the foregoing describes a number of separate embodiments, what has been described herein is merely illustrative of the application of the principles of the present invention. Additionally, although particular methods herein may be illustrated and/or described as being performed in a specific order, the ordering is highly variable within ordinary skill to achieve aspects of the present disclosure. Accordingly, this description is meant to be taken only by way of example, and not to otherwise limit the scope of this disclosure.

Exemplary embodiments have been disclosed above and illustrated in the accompanying drawings. It will be understood by those skilled in the art that various changes, omissions and additions may be made to that which is specifically disclosed herein without departing from the spirit and scope of the present disclosure.

1. A machine-implemented method of automatedly managing operation of an electrochemical storage device, the machine-implemented method comprising:
receiving a real-time time series based on data from one or more sensors that monitor one or more operating conditions of the electrochemical storage device;
clustering the real-time time series into an anomaly group that denotes that an anomaly in the electrochemical storage device has occurred, wherein parameters for the anomaly group have been determined using a machine-learning model trained on a plurality of training time-series data sets; and
when the anomaly is determined to have occurred via the processing, taking a predetermined operation-control action based on the anomaly group.

2. The machine-implemented method of claim 1, wherein the clustering requires an input having a fixed format, and the method further includes modifying the real-time time series to conform to the fixed format prior to the clustering.

3. The machine-implemented method of claim 2, wherein the modifying includes statistically modifying the real-time time series.

4. The machine-implemented method of claim 1, further comprising:
prior to the clustering of the real-time time series, determining whether or not the real-time time series meets at least one anomaly-indicating criterion; and
only when the determining determines that the real-time time series meets the at least one anomaly-indicating criterion, proceeding to the clustering of the real-time time series.

5. The machine-implemented method of claim 4, wherein the determining of whether or not the real-time time series meets at least one anomaly-indicating criterion includes processing the real-time time series to determine a data characterization.

6. The machine-implemented method of claim 5, wherein the data characterization comprises a reconstruction error.

7. The machine-implemented method of claim 5-6, wherein proceeding to the clustering of the real-time time series occurs only when the data characterization exceeds a predetermined threshold.

8. The machine-implemented method of claim 4, wherein determining whether or not the real-time time series meets at least one anomaly-indicating criterion includes processing the real-time time series data with an autoencoder to determine a reconstruction error.

9. The machine-implemented method of claim 8, wherein the at least one anomaly-indicating criterion comprises a reconstruction-error threshold.

10. The machine-implemented method of claim 1, wherein clustering the real-time time series includes clustering the real-time time series using a trained clustering model.

11. The machine-implemented method of claim 1, wherein the clustering of the real-time time series includes executing a clustering model that has been trained to cluster a plurality of differing anomalies that include the anomaly group of the real-time time series.

12. The machine-implemented method of claim 11, further comprising selecting the predetermined operation-control action from a plurality of predetermined operation-control actions corresponding respectively to the plurality of differing anomalies.

13. The machine-implemented method of claim 1, wherein the operation-control action comprises changing the operation of at least one electrochemical cell of the electrochemical storage device.

14. (canceled)

15. (canceled)

16. The machine-implemented method of claim 1, wherein the operation-control action comprises displaying a notification concerning the anomaly.

17. The machine-implemented method of claim 1, wherein the anomaly has a type, and the operation-control action includes displaying the type of the anomaly.

18. A battery management system that performs a method according to claim 1.

19. A battery testing system that performs a method according to claim 1.

20. A machine-readable medium containing machine-executable instructions for performing a method according to claim 1. (Original) A method of creating an anomaly handler for a management system for managing operation of an electrochemical storage device, the method comprising:
receiving an input plurality of time-series data sets containing operating data acquired from multiple training storage devices that each share a fundamental design with the electrochemical storage device to be operated by the management system;
training a clustering model to create a trained clustering model, wherein the training includes using ones of the input plurality of time-series data sets so as to create a trained clustering model configured to cluster, when the anomaly handler is deployed in the management system, real-time time-series operating data as indicating presence of an anomaly in the electrochemical storage device; and
deploying the trained clustering model in the anomaly handler.

22. The method of claim 21, wherein training a clustering model includes training a clustering model using the ones of the input plurality of time-series data sets.

23. The method of either claim 21, wherein the ones of the input plurality of time-series data sets are only time-series data sets that indicate an anomaly has occurred in a corresponding one of the training storage devices.

24. The method of claim 21, further comprising:
training a detection model to create a trained detection model that, when the anomaly handler is deployed in the management system, generates a data characterization of the real-time time-series operating data; and
deploying the trained detection model in the anomaly handler.

25. (canceled)

26. (canceled)

27. The method of claim 24, further comprising providing a data-characterization threshold for distinguishing, via the data characterization, when the real-time time series indicates that the electrochemical storage device is experiencing an anomalous event from when the real-time time series indicates that the real-time time series does not indicate that the electrochemical storage device is not experiencing an anomalous event.

28. The method of claim 27, wherein the data characterization includes a reconstruction error, and the data-characterization threshold comprises a reconstruction error.

29. The method of claim 27, further comprising providing a filter that sends the real-time time series to the clustering model only when the data characterization for the real-time time series indicates that the electrochemical storage device is experiencing an anomalous event.

30. A method of making a management system for operating an electrochemical storage device, the method including:
performing the method of claim 21 so as to create the anomaly handler; and
deploying the anomaly handler in the management system.
